(19) United States
(12) Patent Application Publication
(10) Pub. No.: US 2026/0173799 A1
(43) Pub. Date: Jun. 18, 2026

(54) SEMICONDUCTOR MANUFACTURING APPARATUS HAVING OPTICAL WINDOW

(71) Applicant: Samsung Electronics Co., Ltd., Suwon-si (KR)

(72) Inventors: Daesan Choi, Suwon-si (KR); JUNGSHIN LEE, Suwon-si (KR); Juno Kim, Suwon-si (KR); TAEGYU KANG, Suwon-si (KR); JONGHO LEE, Suwon-si (KR); JAE-SEON HWANG, Suwon-si (KR)

(21) Appl. No.: 19/424,456

(22) Filed: Dec. 18, 2025

(30) Foreign Application Priority Data
Dec. 18, 2024 (KR) 10-2024-0189934

(51) Int. Cl. H10P 72/00

(52) U.S. Cl. CPC H10P 72/0604; H10P 72/0402

(57) ABSTRACT

A semiconductor manufacturing apparatus includes a chamber having an inner space, an optical window dividing the inner space into a processing space and a buffer space, a stage disposed in the processing space and that having a support surface configured to support a substrate, and a light source disposed in the buffer space and configured to irradiate the stage with light through the optical window, and the optical window has communication holes defined therein providing a fluid path between the processing space and the buffer space.

### CROSS-REFERENCE TO RELATED APPLICATIONS

This application claims priority under 35 U.S.C. § 119 to Korean Patent Application No. 10-2024-0189934 filed on Dec. 18, 2024, in the Korean Intellectual Property Office, the disclosures of which are incorporated by reference herein in their entireties.

### BACKGROUND

Embodiments of the present disclosure described herein relate to a semiconductor manufacturing apparatus, and more particularly, relate to a semiconductor manufacturing apparatus including an optical window.

A semiconductor device may be manufactured by various manufacturing processes. Some manufacturing processes (e.g., an annealing process, a dicing process, a trimming process, and a bonding process) may be performed using light. Since the processes using the light are capable of having a high energy density in an ultra-fine area of the semiconductor device, the utilization thereof is increasing according to the trend of high integration of semiconductor devices. In order to perform a high-quality process, the light radiated onto a substrate should be uniform. Accordingly, a light source and an optical window may benefit from being protected from contamination by fumes generated in a semiconductor manufacturing process.

### SUMMARY

Embodiments of the present disclosure provide a semiconductor manufacturing apparatus with improved optical uniformity.

Embodiments of the present disclosure provide a semiconductor manufacturing apparatus for minimizing contamination of a light source.

Embodiments of the present disclosure provide a semiconductor manufacturing apparatus for minimizing contamination of an optical window.

Embodiments of the present disclosure provide a semiconductor manufacturing apparatus for rapidly and smoothly discharging fumes generated in a manufacturing process.

Embodiments of the present disclosure provide a semiconductor manufacturing apparatus for forming a downdraft to remove fumes generated in a manufacturing process.

According to an embodiment, a semiconductor manufacturing apparatus includes a chamber having an inner space, an optical window dividing the inner space into a processing space and a buffer space, a stage disposed in the processing space and having a support surface configured to support a substrate, and a light source disposed in the buffer space and configured to irradiate the stage with light through the optical window, and the optical window has a plurality of communication holes defined therein providing a fluid path between the processing space and the buffer space.

According to an embodiment, a semiconductor manufacturing apparatus includes a chamber having an inner space, a stage disposed in the inner space and having a support surface configured to support a substrate, a light source disposed in the inner space and that irradiates the stage with light, and an optical window located between the stage and the light source. The optical window includes a first optical plate including a plurality of first optical patterns spaced apart to define a plurality of first communication holes and a second optical plate that is spaced apart from the first optical plate in a vertical direction perpendicular to a surface of the first optical plate, and that includes a plurality of second optical patterns spaced apart to define a plurality of second communication holes. The plurality of first optical patterns vertically overlap the plurality of second communication holes, respectively, but do not vertically overlap the plurality of second optical patterns.

According to an embodiment, a semiconductor manufacturing apparatus includes a chamber having an inner space, an optical window dividing the inner space into a processing space and a buffer space, a stage disposed in the processing space and having a support surface configured to support a substrate, a light source disposed in the buffer space and that irradiates the stage with light through the optical window, a supply pipe that supplies a purge gas into the buffer space, and a discharge pipe that discharges the purge gas supplied by the supply pipe from the processing space. The optical window has a plurality of communication holes providing a fluid path between the buffer space and the processing space. The buffer space is located over the optical window, and the processing space is located under the optical window. The purge gas flows from the buffer space into the processing space through the plurality of communication holes when the purge gas is supplied by the supply pipe.

### BRIEF DESCRIPTION OF THE FIGURES

The above and other objects and features of the present disclosure will become apparent by describing in detail embodiments thereof with reference to the accompanying drawings.

FIG. 1 is a perspective view of an optical window according to an embodiment of the present disclosure.

FIG. 2 is a sectional view taken along line I-I′ of FIG. 1.

FIG. 3 is a sectional view of a semiconductor manufacturing apparatus according to an embodiment of the present disclosure.

FIG. 4 is a sectional view of an optical window according to an embodiment of the present disclosure, where FIG. 4 is a sectional view corresponding to line I-I′ of FIG. 1.

FIG. 5 is a sectional view of an optical window according to an embodiment of the present disclosure, where FIG. 5 is a sectional view corresponding to line I-I′ of FIG. 1.

FIG. 6 is a sectional view of an optical window according to an embodiment of the present disclosure, where FIG. 6 is a sectional view corresponding to line I-I′ of FIG. 1.

FIG. 7 is a sectional view of an optical window according to an embodiment of the present disclosure, where FIG. 7 is a sectional view corresponding to line I-I′ of FIG. 1.

FIG. 8 is a sectional view of an optical window according to an embodiment of the present disclosure, where FIG. 8 is a sectional view corresponding to line I-I′ of FIG. 1.

FIG. 9 is a sectional view of an optical window according to an embodiment of the present disclosure, where FIG. 9 is a sectional view corresponding to line I-I′ of FIG. 1.

### DETAILED DESCRIPTION

Hereinafter, embodiments of the present disclosure will be described clearly and in detail with reference to the accompanying drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. Semiconductor packages may include a package substrate, one or more semiconductor chips, and an encapsulant formed on the package substrate and covering the semiconductor chips.

The term “substrate” may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.), or a stack structure including such a base substrate and layers formed on the base substrate.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. As used herein, items described as being “fluidly connected” are configured such that a liquid or gas can flow, or be passed, from one item to the other. Such connection may provide a fluid path through which a fluid may pass from one item to the other.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

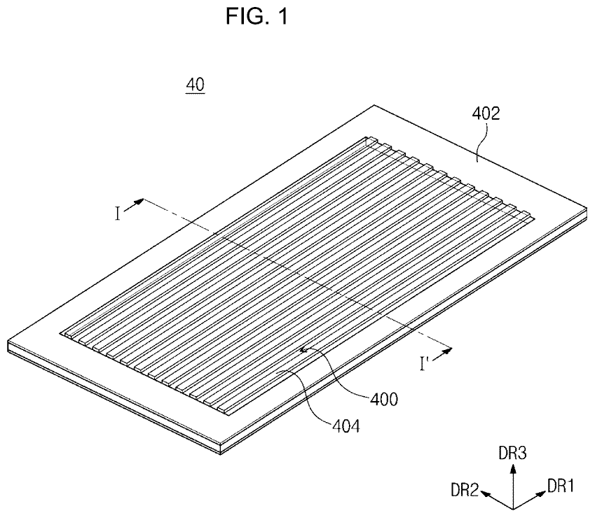

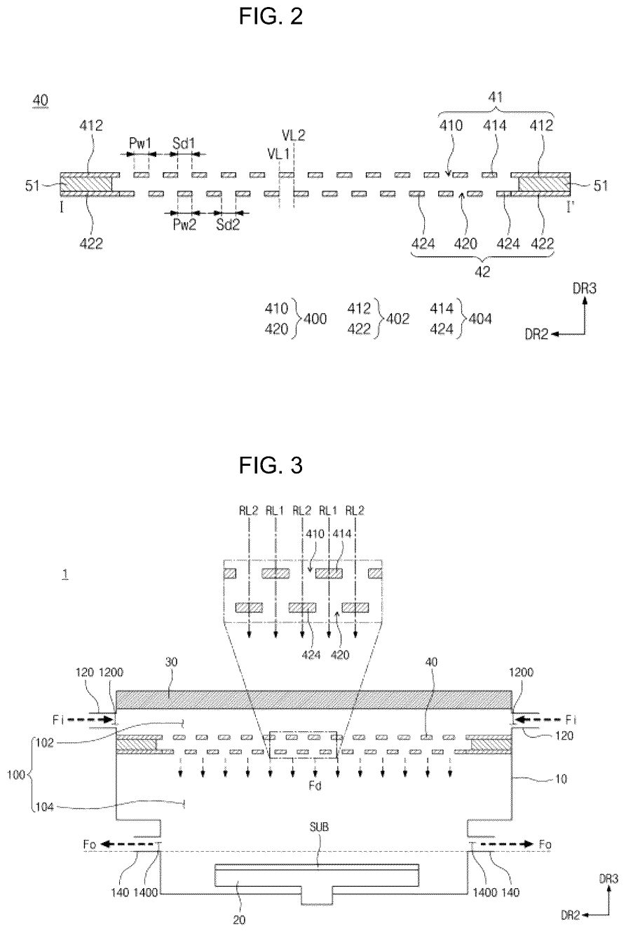

FIG. 1 is a perspective view of an optical window 40 according to an embodiment of the present disclosure. FIG. 2 is a sectional view taken along line I-I′ of FIG. 1.

Referring to FIGS. 1 and 2, the optical window 40 may include one or more optical plates which may each include a frame 402 and a plurality of optical patterns 404. The frame 402 may define the outer shape of the optical window 40. The frame 402 may surround and/or define an aperture. The plurality of optical patterns 404 may cover portions of the aperture.

The optical patterns 404 may be coupled to the frame 402. The optical patterns 404 may extend from the frame 402 and may cross the aperture. The optical patterns 404 may be integrated with the frame 402. The optical patterns 404 may extend lengthwise in one direction, and the frame 402 may extend lengthwise in the one direction as well. The optical patterns 404 may be spaced apart from one another in another direction crossing the one direction. For example, the optical patterns 404 may extend lengthwise in a first direction DR1 and may be spaced apart from one another in a second direction DR2 perpendicular to the first direction DR1.

Communication holes 400 may be defined between neighboring ones of the optical patterns 404. The communication holes 400 may also be defined between the optical patterns 404 and the frame 402. The communication holes 400 may be defined between the optical patterns 404 extending lengthwise and may extend lengthwise in the extension direction of the optical patterns 404. For example, the communication holes 400 may extend lengthwise in the first direction DR1 and may be spaced apart from one another in the second direction DR2 perpendicular to the first direction DR1. The communication holes 400 may be spaced apart from one another by the width of one of the optical patterns 404. For example, the communication holes 400 may be slots defined by the optical patterns 404. The communication holes may provide a fluid path through the optical window 40.

The optical window 40 may include a light transmissive material (e.g., the optical window 40 may allow for light to be transmitted therethrough). The optical patterns 404 may include a light transmissive material (e.g., the optical patterns 404 may allow for light to be transmitted therethrough). The frame 402 may include a light transmissive material (e.g., the frame 402 may allow for light to be transmitted therethrough). For example, the optical patterns 404 may include quartz. However, without being limited thereto, the optical patterns 404 may include various materials depending on the wavelength and bandwidth of light used. Accordingly, the optical window 40 may transmit light.

The optical window 40 may have a multi-layer structure of multiple optical plates. The optical plates may be vertically stacked (e.g., stacked in a third direction DR3 perpendicular to the first direction DR1 and the second direction DR2) and spaced apart from each other. Each of the optical plates may include the frame 402 and the optical patterns 404 that define the communication holes 400. The optical patterns 404 of one of the optical plates may not overlap the optical patterns 404 of another one of the optical plates. For example, the optical patterns 404 of a first optical plate of the optical plates may be staggered with respect to the optical patterns 404 of a second one of the optical plates. Accordingly, the communication holes 400 defined in the first optical plate may be staggered with respect to the communication holes 400 defined in other ones of the optical plates.

For example, the optical window 40 may include a first optical plate 41 including first optical patterns 414 that define first communication holes 410. The first optical plate 41 may include a light transmissive material.

For example, the first optical patterns 414 may extend lengthwise in the first direction DR1 and may be spaced apart from one another in the second direction DR2 crossing the first direction DR1. The first communication holes 410 may be defined between neighboring ones of the first optical patterns 414 spaced apart from one another.

The first optical plate 41 may include a first frame 412 to which the first optical patterns 414 are coupled. The first communication holes 410 may also be defined between the first frame 412 and the first optical patterns 414.

Each of the first optical patterns 414 may have a constant width. Each of the first communication holes 410 may have a constant width. The widths of the first communication holes 410 may be defined as the separation gaps between the first optical patterns 414. The widths of the first optical patterns 414 and the widths of the first communication holes 410 may be defined in the second direction DR2. For example, the width of each of the first optical patterns 414 in the second direction DR2 may be defined as a first width Pw1, and the width of each of the first communication holes 410 in the second direction DR2 may be defined as a first gap Sd1.

The optical window 40 may include a second optical plate 42 including second optical patterns 424 that define second communication holes 420. The second optical plate 42 may include a light transmissive material.

The second optical plate 42 may be vertically spaced apart from the first optical plate 41 (e.g., may be offset in the third direction DR3). For example, the second optical plate 42 may be disposed under the first optical plate 41. However, without being limited thereto, the second optical plate 42 may be disposed over the first optical plate 41.

The second optical patterns 424 may extend long in the extension direction of the first optical patterns 414 and may be spaced apart from one another in the direction in which the first optical patterns 414 are arranged. For example, the second optical patterns 424 may extend lengthwise in the first direction DR1 and may be spaced apart from one another in the second direction DR2. The second communication holes 420 may be defined between neighboring ones of the second optical patterns 424 spaced apart from one another.

The second optical plate 42 may include a second frame 422 to which the second optical patterns 424 are coupled. The second communication holes 420 may also be defined between the second frame 422 and the second optical patterns 424.

Each of the second optical patterns 424 may have a constant width. Each of the second communication holes 420 may have a constant width. The widths of the second communication holes 420 may be defined as the separation gaps between the second optical patterns 424. The widths of the second optical patterns 424 and the widths of the second communication holes 420 may be defined in the second direction DR2. For example, the width of each of the second optical patterns 424 in the second direction DR2 may be defined as a second width Pw2, and the width of each of the second communication holes 420 in the second direction DR2 may be defined as a second gap Sd2.

The widths of the second optical patterns 424 may correspond to the widths of the first communication holes 410. The widths of the second optical patterns 424 may correspond to the separation gaps between the first optical patterns 414. For example, the second widths Pw2 of the second optical patterns 424 may be substantially the same as the first gaps Sd1 between the first optical patterns 414.

The widths of the first optical patterns 414 may correspond to the widths of the second communication holes 420. The widths of the first optical patterns 414 may correspond to the separation gaps between the second optical patterns 424. For example, the first widths Pw1 of the first optical patterns 414 may be substantially the same as the second gaps Sd2 between the second optical patterns 424.

The first optical patterns 414 may not vertically overlap the second optical patterns 424. For example, the first optical patterns 414 may not overlap the second optical patterns 424 when viewed in a plan view. For example, the first optical patterns 414 may be staggered with respect to the second optical patterns 424 when viewed in the plan view.

The first optical patterns 414 and the second optical patterns 424 may be alternately arranged in the second direction DR2. For example, the first optical patterns 414 and the second optical patterns 424 may be alternately arranged when viewed in the plan view (e.g., the first optical patterns 414 may align with the second communication holes 420 in a plan view). The first optical patterns 414 may be located between the second optical patterns 424 when viewed in the plan view.

For example, first ends and second ends of the first optical patterns 414 in the width direction (e.g., the second direction DR2) may be vertically aligned with first ends and second ends of the second optical patterns 424 in the width direction (e.g., the second direction DR2). Likewise, the first ends and the second ends of the second optical patterns 424 in the width direction (e.g., the second direction DR2) may be vertically aligned with the first ends and the second ends of the first optical patterns 414 in the width direction (e.g., the second direction DR2). For example, the first end of one of the first optical patterns 414 in the second direction DR2 and the first end of one of the second optical patterns 424 in the second direction DR2 may both be located on a common first vertical line VL1. In addition, the second end of the one of the first optical patterns 414 in the second direction DR2 and the second end of another one of the second optical patterns 424 in the second direction DR2 may both be located on a common second vertical line VL2.

The first optical patterns 414 may vertically overlap the second communication holes 420, respectively. For example, the first optical patterns 414 may completely overlap the second communication holes 420, respectively. For example, the first optical patterns 414 may cover the second communication holes 420 from above, respectively. For example, the first optical patterns 414 may cover the whole second communication holes 420 from above, respectively. Accordingly, the second communication holes 420 may not be exposed upward when viewed in the plan view.

The second optical patterns 424 may vertically overlap the first communication holes 410, respectively. For example, the second optical patterns 424 may completely overlap the first communication holes 410, respectively. For example, the second optical patterns 424 may cover the first communication holes 410 from below, respectively. For example, the second optical patterns 424 may cover the whole first communication holes 410 from below, respectively. Accordingly, the first communication holes 410 may not be exposed downward when viewed in the plan view.

In an embodiment, the first optical patterns 414 may have substantially the same thickness as the second optical patterns 424. Accordingly, the first optical patterns 414 may have substantially the same light transmittance as the second optical patterns 424.

The optical window 40 may further include spacers provided between the optical plates. The spacers may vertically space the optical plates apart from each other. For example, the optical window 40 may include a first spacer 51 vertically spacing the first optical plate 41 and the second optical plate 42 apart from each other.

Accordingly, the uniformity of light transmitting through the optical window 40 may be improved. For example, referring to FIG. 3, light RL1 transmitting through the first optical patterns 414 may pass through the second communication holes 420 and may be radiated into a processing space, and light RL2 passing through the first communication holes 410 may transmit through the second optical patterns 424 and may be radiated into the processing space. As a result, light may be uniformly radiated into the processing space as the light is transmitted through only one of the first optical patterns 414 and the second optical patterns 424. For example, the light RL1 transmitting through the first optical patterns 414 and the light RL2 transmitting through the first communication holes 410 may have uniform energy relative to one another.

In addition, the first optical patterns 414 may have substantially the same thickness as the second optical patterns 424. As a result, the thicknesses of the optical patterns through which the light RL1 incident to the optical window 40 through the first optical patterns 414 transmits may be substantially the same as the thicknesses of the optical patterns through which the light RL2 incident to the optical window 40 through the first communication holes 410 transmits.

Accordingly, the energy of light radiated onto a substrate may be uniform across the substrate (e.g., the substrate may be uniformly irradiated).

FIG. 3 is a sectional view of a semiconductor manufacturing apparatus 1 according to an embodiment of the present disclosure.

Referring to FIG. 3, the semiconductor manufacturing apparatus 1 may include a chamber 10 including an inner space 100, a stage 20 provided in the chamber 10, and a light source 30 provided in the chamber 10.

The chamber 10 may include the inner space 100 (e.g., the chamber 10 may define and/or enclose the inner space). The optical window 40 may be provided in the inner space 100. The optical window 40 may divide the inner space 100 into a processing space 104 and a buffer space 102. The optical window 40 may fluidically connect the processing space 104 and the buffer space 102. For example, the optical window 40 may vertically divide the inner space 100 into the buffer space 102 and the processing space 104, and the buffer space 102 may be located over the processing space 104.

The stage 20 may be provided in the processing space 104. A substrate SUB may be loaded on the stage 20. The substrate SUB loaded on the stage 20 may be processed in the processing space 104. The stage 20 may have a support surface for supporting the substrate SUB. For example, the stage 20 may have a horizontal planar surface on which the substrate SUB can be placed, but embodiments are not limited thereto.

The substrate SUB may be a reconstituted substrate. For example, the reconstituted substrate having a wafer shape may be formed by rearranging semiconductor chips obtained by cutting a wafer and providing a molding film to the rearranged semiconductor chips. The substrate may include interposer chips and may have at least one semiconductor package provided on each of the interposer chips.

The light source 30 may be provided in the buffer space 102. The light source 30 may radiate light into the processing space 104. For example, the light emitted from the light source 30 may transmit through the optical window 40 and may be radiated into the processing space 104. For example, the light transmitting through the optical window 40 may be radiated onto the substrate SUB loaded on the stage 20 (e.g., the substrate SUB loaded on the stage 20 may be irradiated by the light transmitted through the optical window 40). Accordingly, a manufacturing process may be performed on the substrate SUB. The light source 30 may include a laser, a flash lamp, or a halogen lamp, but examples are not limited thereto.

The optical window 40 may minimize a phenomenon in which fumes generated in a process of processing the substrate SUB are introduced into the buffer space 102. The fumes may include hazardous gases, vapors, or fine particles generated in the manufacturing process. Specifically, the optical window 40 may minimize a phenomenon in which fumes generated in the processing space 104 contaminate an emission surface of the light source 30 disposed in the buffer space 102. Accordingly, the light source 30 may radiate uniform light into the processing space 104.

The semiconductor manufacturing apparatus 1 may include a supply pipe 120 and a discharge pipe 140 that are connected to the chamber 10. The chamber 10 may include an inlet 1200 to which the supply pipe 120 is connected. The supply pipe 120 may be connected to the inlet 1200 and may supply (Fi) a gas into the buffer space 102. The gas may be a purge gas. The supply pipe 120 may be connected to a side surface of the chamber 10. For example, the inlet 1200 may be provided in the side surface of the chamber 10. Accordingly, the purge gas may be supplied (Fi) into the buffer space 102 in a lateral direction from the side surface of the chamber 10. Accordingly, the purge gas supplied into the buffer space 102 through the supply pipe 120 may be evenly distributed in a horizontal direction and may be evenly supplied into the processing space 104 through the communication holes 400.

However, without being limited thereto, the supply pipe 120 may be connected to the upper side of the chamber 10 and may supply the purge gas. A plurality of inlets 1200 through which the purge gas is supplied into the buffer space 102 via the supply pipe 120 may be provided on the upper side of the chamber 10. In this case, the inlets 1200 and the light source 30 may be staggered with respect to each other so as not to overlap each other. Accordingly, the purge gas may be evenly supplied to the buffer space 102 and the optical window 40.

Furthermore, the first communication holes 410 and the second communication holes 420 illustrated in FIGS. 1 and 2 are exaggerated for convenience of description. The first communication holes 410 and the second communication holes 420 actually provided may be provided at a ratio smaller than the ratio of FIG. 2. For example, the widths of the first communication holes 410 and the second communication holes 420 may be adjusted to be sufficiently small such that the purge gas supplied from the supply pipe 120 evenly passes through the entirety of the first communication holes 410 and the second communication holes 420 and is evenly supplied into the processing space 104.

The semiconductor manufacturing apparatus 1 may further include a compressor (not illustrated) that supplies the gas into the buffer space 102 through the supply pipe 120.

The gas supplied into the buffer space 102 may flow (Fd) into the processing space 104 through the optical window 40. For example, the gas in the buffer space 102 may flow (Fd) into the processing space 104 through the communication holes of the optical window 40.

The chamber 10 may include an outlet 1400 to which the discharge pipe 140 is connected. The outlet 1400 may be provided beside the stage 20. For example, the outlet 1400 may be adjacent to the stage 20. The discharge pipe 140 may be connected to the outlet 1400, and the gas in the processing space 104 may be discharged (Fo) through the discharge pipe 140.

The discharge pipe 140 may be connected to the side surface of the chamber 10. For example, the outlet 1400 may be provided in the side surface of the chamber 10. The outlet 1400 may be located below the inlet 1200.

Accordingly, the gas in the chamber 10 may form a downdraft Fd. The downdraft Fd may reduce a phenomenon in which the fumes generated in the process of processing the substrate SUB flow upward. The downdraft Fd may also minimize contamination of the optical window 40 by the fumes.

In addition, the fumes generated in the process of processing the substrate SUB may be smoothly and rapidly discharged (Fo) through the adjacent outlet 1400. Accordingly, the duration of stay of the fumes in the processing space 104 may be reduced. Furthermore, contamination of the inner surface of the chamber 10 by the fumes may also be minimized.

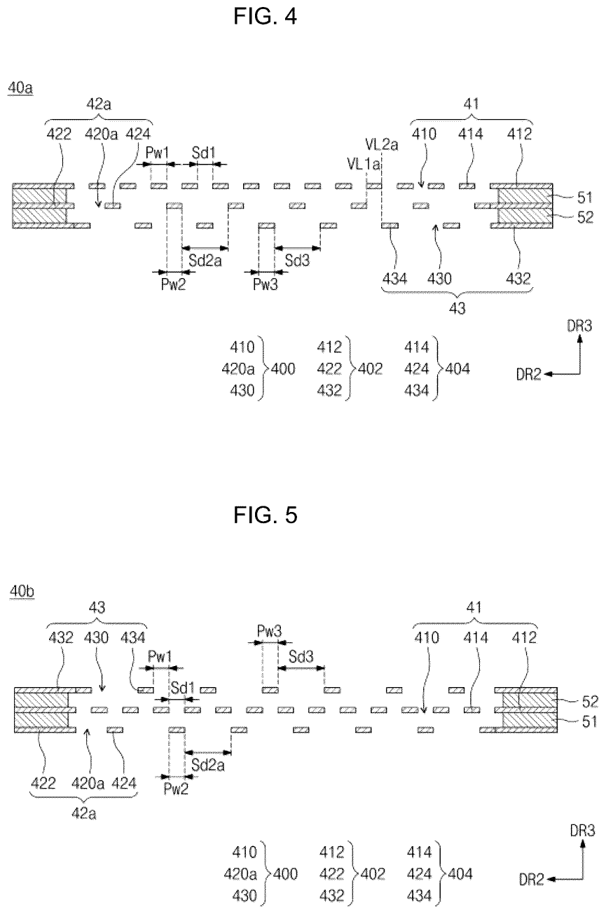

FIG. 4 is a sectional view of an optical window 40a according to an embodiment of the present disclosure, where FIG. 4 is a sectional view corresponding to line I-I′ of FIG. 1.

For convenience of description, the optical window 40a will be described focusing on the difference from the optical window 40 described above.

Referring to FIG. 4, in an embodiment, the optical window 40a may include three or more optical plates 41, 42a, and 43. The optical plates 41, 42a, and 43 may include optical patterns 414, 424, and 434, respectively. The thicknesses of optical patterns through which light vertically incident to one point of the optical window 40a transmits may be substantially the same as the thicknesses of optical patterns through which light vertically incident to another point of the optical window 40a transmits. Accordingly, the intensity of the light vertically incident to the one point of the optical window 40a and output from the optical window 40a may be substantially the same as the intensity of the light vertically incident to the other point of the optical window 40a and output from the optical window 40a.

The optical window 40a may further include the third optical plate 43. The third optical plate 43 may be vertically arranged with the first optical plate 41 and the second optical plate 42a. The third optical plate 43 may be vertically spaced apart from the first optical plate 41 and the second optical plate 42a. For example, the third optical plate 43 may be disposed under the first optical plate 41 and the second optical plate 42a.

The third optical plate 43 may include the third optical patterns 434 that define third communication holes 430 and a third frame 432 to which the third optical patterns 434 are coupled.

The third optical patterns 434 may extend lengthwise in the extension direction of the first optical patterns 414 and may be spaced apart from one another in the direction in which the first optical patterns 414 are arranged. For example, the third optical patterns 434 may extend lengthwise in the first direction DR1 and may be spaced apart from one another in the second direction DR2. The third communication holes 430 may be defined between the third optical patterns 434 spaced apart from one another. The third communication holes 430 may also be defined between the third frame 432 and the third optical patterns 434.

Each of the third optical patterns 434 may have a constant width. Each of the third communication holes 430 may have a constant width. The widths of the third communication holes 430 may be defined as the separation gaps between the third optical patterns 434. The widths of the third optical patterns 434 and the widths of the third communication holes 430 may be defined in the second direction DR2.

The widths of the second optical patterns 424 may correspond to the widths of first communication holes 410. The widths of the second optical patterns 424 may correspond to the separation gaps between the first optical patterns 414. For example, the second widths Pw2 of the second optical patterns 424 may be substantially the same as the first gaps Sd1 between the first optical patterns 414.

Likewise, the widths of the third optical patterns 434 may correspond to the widths of the first communication holes 410. The widths of the third optical patterns 434 may correspond to the separation gaps between the first optical patterns 414. For example, the third widths Pw3 of the third optical patterns 434 may be substantially the same as the first gaps Sd1 between the first optical patterns 414.

The widths Sd2a of second communication holes 420a may be greater than the widths Sd1 of the first communication holes 410. The widths Sd3 of the third communication holes 430 may be greater than the widths Sd1 of the first communication holes 410 For example, the widths Sd1 of the first communication holes 410 may be smaller than the widths Sd2a of the second communication holes 420a and the widths Sd3 of the third communication holes 430. In an embodiment, the widths Sd2a of the second communication holes 420a and the widths Sd3 of the third communication holes 430 may be substantially the same as each other.

The first to third optical patterns 414, 424, and 434 may not vertically overlap one another. For example, the first to third optical patterns 414, 424, and 434 may not overlap one another when viewed in a plan view. The first to third optical patterns 414, 424, and 434 may be staggered with respect to one another when viewed in the plan view.

The first communication holes 410 may vertically overlap the second optical patterns 424 and the third optical patterns 434. Specifically, some of the first communication holes 410 may vertically overlap the second optical patterns 424. The other first communication holes 410 may vertically overlap the third optical patterns 434.

First ends and second ends of the first optical patterns 414 in the width direction may be vertically aligned with first ends of the second optical patterns 424 in the width direction and first ends of the third optical patterns 434 in the width direction. For example, the first end of one of the first optical patterns 414 in the second direction DR2 and the first end of one of the second optical patterns 424 in the second direction DR2 may each be located on a common first vertical line VL1a. In addition, the second end of one of the first optical patterns 414 in the second direction DR2 and the first end of one of the third optical patterns 434 in the second direction DR2 may each be located on a common second vertical line VL2a.

The first optical patterns 414 may vertically overlap the second communication holes 420a and the third communication holes 430, respectively. The second optical patterns 424 may vertically overlap the first communication holes 410 and the third communication holes 430, respectively. The third optical patterns 434 may vertically overlap the first communication holes 410 and the second communication holes 420a, respectively. Accordingly, light emitted from the light source 30 may transmit through one of the first to third optical patterns 414, 424, and 434 and may be radiated into the processing space 104.

The optical window 40a may further include a second spacer 52 provided between the second optical plate 42a and the third optical plate 43. The second spacer 52 may vertically space the second optical plate 42a and the third optical plate 43 apart from each other.

FIG. 5 is a sectional view of an optical window 40b according to an embodiment of the present disclosure, where FIG. 5 is a sectional view corresponding to line I-I′ of FIG. 1.

For convenience of description, the optical window 40b will be described focusing on the difference from the optical windows 40 and 40a described above.

Referring to FIG. 5, in an embodiment, a first optical plate may be provided between a second optical plate and a third optical plate.

Likewise, in this case, first to third optical patterns 414, 424, and 434 may not vertically overlap one another. That is, the first to third optical patterns 414, 424, and 434 may not overlap one another when viewed in a plan view. The first to third optical patterns 414, 424, and 434 may be staggered with respect to one another when viewed in the plan view.

First communication holes 410 may vertically overlap the second optical patterns 424 and the third optical patterns 434. For example, some of the first communication holes 410 may vertically overlap the second optical patterns 424. The other first communication holes 410 may vertically overlap the third optical patterns 434.

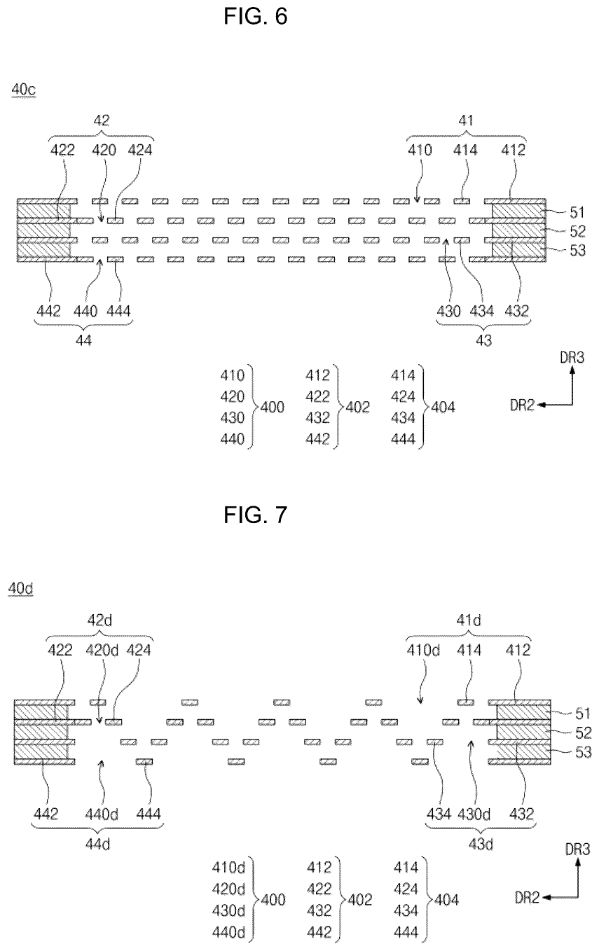

FIG. 6 is a sectional view of an optical window 40c according to an embodiment of the present disclosure, where FIG. 6 is a sectional view corresponding to line I-I′ of FIG. 1.

For convenience of description, the optical window 40c will be described focusing on the difference from the optical windows 40, 40a, and 40b described above.

Referring to FIG. 6, in an embodiment, the optical window 40c may further include a third optical plate 43 and a fourth optical plate 44 that are vertically spaced apart from a first optical plate 41 and a second optical plate 42. The third optical plate 43 and the fourth optical plate 44 may be vertically spaced apart from each other.

In this case, the third optical plate 43 may include substantially the same structure as the first optical plate 41. In addition, the fourth optical plate 44 may include substantially the same structure as the second optical plate 42.

Accordingly, specifically, first optical patterns 414 may not vertically overlap second optical patterns 424. That is, the first optical patterns 414 may not overlap the second optical patterns 424 when viewed in a plan view. The first optical patterns 414 may be staggered with respect to the second optical patterns 424 when viewed in the plan view.

The first optical patterns 414 may vertically overlap third optical patterns 434. The first optical patterns 414 and the third optical patterns 434 may vertically overlap second communication holes 420 and fourth communication holes 440.

For example, the first optical patterns 414 and the third optical patterns 434 may completely overlap the second communication holes 420 and the fourth communication holes 440, respectively. For example, the first optical patterns 414 and the third optical patterns 434 may cover the second communication holes 420 and the fourth communication holes 440 from above, respectively. For example, the first optical patterns 414 may cover the whole second communication holes 420 from above, respectively, and the third optical patterns 434 may cover the whole fourth communication holes 440 from above, respectively. Accordingly, the second communication holes 420 and the fourth communication holes 440 may not be exposed upward when viewed in the plan view.

The second optical patterns 424 may vertically overlap fourth optical patterns 444. The second optical patterns 424 and the fourth optical patterns 444 may vertically overlap first communication holes 410 and third communication holes 430.

For example, the second optical patterns 424 and the fourth optical patterns 444 may completely overlap the first communication holes 410 and the third communication holes 430, respectively. For example, the second optical patterns 424 and the fourth optical patterns 444 may cover the first communication holes 410 and the third communication holes 430 from below, respectively. For example, the second optical patterns 424 may cover the whole first communication holes 410 from below, respectively, and the fourth optical patterns 444 may cover the whole third communication holes 430 from below, respectively. Accordingly, the first communication holes 410 and the third communication holes 430 may not be exposed downward when viewed in the plan view.

Accordingly, the uniformity of light transmitting through the optical window 40c may be improved. Specifically, light transmitting through the first optical patterns 414 may sequentially pass through the second communication holes 420, the third optical patterns 434, and the fourth communication holes 440 and may be radiated into the processing space 104, and light passing through the first communication holes 410 may sequentially pass through the second optical patterns 424, the third communication holes 430, and the fourth optical patterns 444 and may be radiated into the processing space 104. In consequence, the light may be uniformly radiated into the processing space 104 because the light transmits through the first optical patterns 414 and the third optical patterns 434 or transmits through the second optical patterns 424 and the fourth optical patterns 444. For example, the light radiated into the processing space 104 may have uniform energy.

FIG. 7 is a sectional view of an optical window 40d according to an embodiment of the present disclosure, where FIG. 7 is a sectional view corresponding to line I-I′ of FIG. 1.

Referring to FIG. 7, in an embodiment, the optical window 40d may further include a third optical plate 43d and a fourth optical plate 44d that are vertically spaced apart from a first optical plate 41d and a second optical plate 42d. The third optical plate 43d and the fourth optical plate 44d may also be vertically spaced apart from each other.

The third optical plate 43d may include third optical patterns 434 that define third communication holes 430d, and a third frame 432. The fourth optical plate 44d may include fourth optical patterns 444 that define fourth communication holes 440d, and a fourth frame 442.

The first to fourth optical patterns 414, 424, 434, and 444 may not vertically overlap one another. First communication holes 410d may completely vertically overlap the second to fourth optical patterns 424, 434, and 444. For example, in one of the first communication holes 410d, a portion of the first communication hole 410d may vertically overlap the second optical pattern 424, another portion of the first communication hole 410d may vertically overlap the third optical pattern 434, and the rest portion of the first communication hole 410d may vertically overlap the fourth optical pattern 444. Accordingly, the whole first communication hole 410d may vertically overlap the second to fourth optical patterns 424, 434, and 444.

Second communication holes 420d may vertically overlap the first optical patterns 414, the third optical patterns 434, and the fourth optical patterns 444. Specifically, some of the second communication holes 420d may vertically overlap the first optical patterns 414. The other second communication holes 420d may vertically overlap the third optical patterns 434 and the fourth optical patterns 444.

For example, in one of the other second communication holes 420d, a portion of the second communication hole 420d may vertically overlap the third optical pattern 434, and the rest portion of the second communication hole 420d may vertically overlap the fourth optical pattern 444. Accordingly, the whole second communication hole 420d may vertically overlap the third optical pattern 434 and the fourth optical pattern 444.

The third communication holes 430d may vertically overlap the first optical patterns 414, the second optical patterns 424, and the fourth optical patterns 444. For example, some of the third communication holes 430d may vertically overlap the fourth optical patterns 444. The other third communication holes 430d may vertically overlap the first optical patterns 414 and the second optical patterns 424.

For example, in one of the other third communication holes 430d, a portion of the third communication hole 430d may vertically overlap the second optical pattern 424, and the rest portion of the third communication hole 430d may vertically overlap the first optical pattern 414. Accordingly, the whole third communication hole 430d may vertically overlap the first optical pattern 414 and the second optical pattern 424.

The fourth communication holes 440d may completely vertically overlap the first to third optical patterns 414, 424, and 434. Specifically, in one of the fourth communication holes 440d, a portion of the fourth communication hole 440d may vertically overlap the third optical pattern 434, another portion of the fourth communication hole 440d may vertically overlap the second optical pattern 424, and the rest portion of the fourth communication hole 440d may vertically overlap the first optical pattern 414. Accordingly, the whole fourth communication hole 440d may vertically overlap the first to third optical patterns 414, 424, and 434.

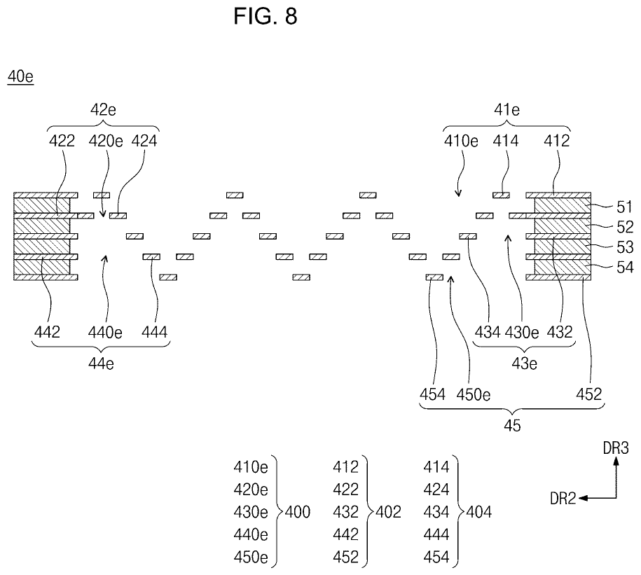

FIG. 8 is a sectional view of an optical window 40e according to an embodiment of the present disclosure, where FIG. 8 is a sectional view corresponding to line I-I′ of FIG. 1.

Referring to FIG. 8, in an embodiment, the optical window 40e may further include a fifth optical plate 45 vertically spaced apart from first to fourth optical plates 41e, 42e, 43e, and 44e. The fifth optical plate 45 may include fifth optical patterns 454 that define fifth communication holes 450, and a fifth frame 452.

The first to fifth optical patterns 414, 424, 434, 444, and 454 may not vertically overlap one another. First communication holes 410e may completely vertically overlap the second to fifth optical patterns 424, 434, 444, and 454. Specifically, in one of the first communication holes 410e, a portion of the first communication hole 410e may vertically overlap the second optical pattern 424, another portion of the first communication hole 410e may vertically overlap the third optical pattern 434, still another portion of the first communication hole 410e may vertically overlap the fourth optical pattern 444, and the rest portion of the first communication hole 410e may vertically overlap the fifth optical pattern 454. Accordingly, the whole first communication hole 410e may vertically overlap the second to fifth optical patterns 424, 434, 444, and 454.

Second communication holes 420e may vertically overlap the first optical patterns 414, the third optical patterns 434, the fourth optical patterns 444, and the fifth optical patterns 454. Specifically, some of the second communication holes 420e may vertically overlap the first optical patterns 414. The other second communication holes 420e may vertically overlap the third to fifth optical patterns 434, 444, and 454.

More specifically, in one of the other second communication holes 420e, a portion of the second communication hole 420e may vertically overlap the third optical pattern 434, another portion of the second communication hole 420e may vertically overlap the fourth optical pattern 444, and the rest portion of the second communication hole 420e may vertically overlap the fifth optical pattern 454. Accordingly, the whole second communication hole 420e may vertically overlap the third to fifth optical patterns 434, 444, and 454.

Third communication holes 430e may vertically overlap the first optical patterns 414, the second optical patterns 424, the fourth optical patterns 444, and the fifth optical patterns 454. Specifically, some of the third communication holes 430e may vertically overlap the first optical patterns 414 and the second optical patterns 424. The other third communication holes 430e may vertically overlap the fourth optical patterns 444 and the fifth optical patterns 454.

More specifically, in one of the some of the third communication holes 430e, a portion of the third communication hole 430e may vertically overlap the second optical pattern 424, and the rest portion of the third communication hole 430e may vertically overlap the first optical pattern 414. Accordingly, the whole third communication hole 430e may vertically overlap the first optical pattern 414 and the second optical pattern 424.

In addition, in one of the other third communication holes 430e, a portion of the third communication hole 430e may vertically overlap the fourth optical pattern 444, and the rest portion of the third communication hole 430e may vertically overlap the fifth optical pattern 454. Accordingly, the whole third communication hole 430e may vertically overlap the fourth optical pattern 444 and the fifth optical pattern 454.

Fourth communication holes 440e may completely vertically overlap the first to third optical patterns 414, 424, and 434 and the fifth optical patterns 454. Specifically, some of the fourth communication holes 440e may vertically overlap the first to third optical patterns 414, 424, and 434. The other fourth communication holes 440e may vertically overlap the fifth optical patterns 454.

For example, in one of the some of the fourth communication holes 440e, a portion of the fourth communication hole 440e may vertically overlap the third optical pattern 434, another portion of the fourth communication hole 440e may vertically overlap the second optical pattern 424, and the rest portion of the fourth communication hole 440e may vertically overlap the first optical pattern 414. Accordingly, the whole fourth communication hole 440e may vertically overlap the first to third optical patterns 414, 424, and 434.

The fifth communication holes 450e may completely vertically overlap the first to fourth optical patterns 414, 424, 434, and 444. For example, in one of the fifth communication holes 450e, a portion of the fifth communication hole 450e may vertically overlap the fourth optical pattern 444, another portion of the fifth communication hole 450e may vertically overlap the third optical pattern 434, still another portion of the fifth communication hole 450e may vertically overlap the second optical pattern 424, and the rest portion of the fifth communication hole 450e may vertically overlap the first optical pattern 414. Accordingly, the whole fifth communication hole 450e may vertically overlap the first to fourth optical patterns 414, 424, 434, and 444.

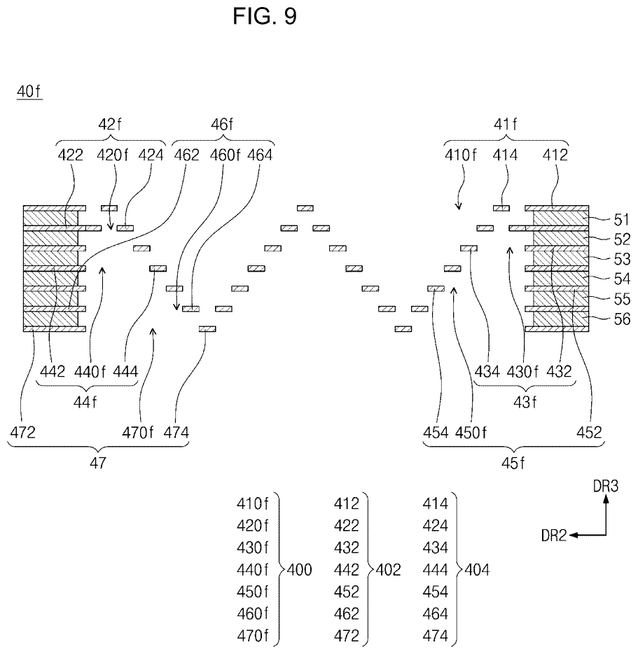

FIG. 9 is a sectional view of an optical window 40f according to an embodiment of the present disclosure, where FIG. 9 is a sectional view corresponding to line I-I′ of FIG. 1.

Referring to FIG. 9, in an embodiment, the optical window 40f may further include a sixth optical plate 46 and a seventh optical plate 47 that are vertically spaced apart from first to fifth optical plates 41f, 42f, 43f, 44f, and 45f. The sixth optical plate 46 and the seventh optical plate 47 may also be vertically spaced apart from each other.

The sixth optical plate 46 may include sixth optical patterns 464 that define sixth communication holes 460f, and a sixth frame 462. The seventh optical plate 47 may include seventh optical patterns 474 that define seventh communication holes 470, and a seventh frame 472.

Likewise, the first to seventh optical patterns 414, 424, 434, 444, 454, 464, and 474 may not vertically overlap one another. First communication holes 410f may completely vertically overlap the second to seventh optical patterns 424, 434, 444, 454, 464, and 474.

Second communication holes 420f may vertically overlap the first optical patterns 414 and the third to seventh optical patterns 434, 444, 454, 464, and 474. Specifically, some of the second communication holes 420f may vertically overlap the first optical patterns 414. The other second communication holes 420f may vertically overlap the third to seventh optical patterns 434, 444, 454, 464, and 474.

Third communication holes 430f may vertically overlap the first optical patterns 414, the second optical patterns 424, and the fourth to seventh optical patterns 444, 454, 464, and 474. Specifically, some of the third communication holes 430f may vertically overlap the first optical patterns 414 and the second optical patterns 424. The other third communication holes 430f may vertically overlap the fourth to seventh optical patterns 444, 454, 464, and 474.

Fourth communication holes 440f may vertically overlap the first to third optical patterns 414, 424, and 434 and the fifth to seventh optical patterns 454, 464, and 474. Specifically, some of the fourth communication holes 440f may vertically overlap the first to third optical patterns 414, 424, and 434. The other fourth communication holes 440f may vertically overlap the fifth to seventh optical patterns 454, 464, and 474.

Fifth communication holes 450f may vertically overlap the first to fourth optical patterns 414, 424, 434, and 444, the sixth optical patterns 464, and the seventh optical patterns 474. Specifically, some of the fifth communication holes 450f may vertically overlap the first to fourth optical patterns 414, 424, 434, and 444. The other fifth communication holes 450f may vertically overlap the sixth optical patterns 464 and the seventh optical patterns 474.

The sixth communication holes 460f may vertically overlap the first to fifth optical patterns 414, 424, 434, 444, and 454 and the seventh optical patterns 474. Specifically, some of the sixth communication holes 460f may vertically overlap the first to fifth optical patterns 414, 424, 434, 444, and 454. The other sixth communication holes 460f may vertically overlap the seventh optical patterns 474.

The seventh communication holes 470f may completely vertically overlap the first to sixth optical patterns 414, 424, 434, 444, 454, and 464.

According to the embodiments of the present disclosure, the semiconductor manufacturing apparatus may minimize contamination of the light source by the fumes through the optical window provided between the processing space and the buffer space. That is, the optical window may minimize the approach of the fumes generated in the processing space to the light source provided in the buffer space.

According to the embodiments of the present disclosure, the optical window may fluidically connect the processing space and the buffer space through the communication holes. Accordingly, the purge gas supplied into the buffer space may flow into the processing space through the communication holes. Thus, the optical window may allow not only light but also the purge gas to pass through the optical window. Furthermore, since the purge gas is directly supplied into the processing space through the communication holes of the optical window, contamination of the optical window by the fumes may be minimized. Accordingly, the uniformity of light transmitting through the optical window may be improved. In addition, the cleaning or replacement cycle of the optical window may be increased, and thus the productivity of a semiconductor manufacturing process may be improved.

According to the embodiments of the present disclosure, since the plurality of communication holes of the optical window are defined between the first optical patterns and the second optical patterns that do not vertically overlap each other, the length of the passage through which the purge gas flows may be increased. Accordingly, the purge gas in the buffer space may be more evenly distributed horizontally in the process of passing through the optical window and may be evenly supplied into the processing space.

According to the embodiments of the present disclosure, due to the buffer space located over the processing space, the purge gas supplied into the buffer space may descend and may flow into the processing space. Due to the downdraft formed in the chamber, it may be difficult for the fumes generated in the processing space to flow into the buffer space located over the processing space. Accordingly, contamination of the chamber, the light source, and the optical window by the fumes may be minimized. In addition, deterioration in the uniformity of light transmitting through the optical window due to contamination of the optical window by the fumes may be minimized.

According to the embodiments of the present disclosure, due to the optical patterns staggered with respect to each other so as not to vertically overlap each other, the light emitted from the light source may be uniformly radiated onto the substrate. In addition, the energy of the light radiated onto the substrate may be uniform.

According to the embodiments of the present disclosure, due to the first communication holes and the second communication holes staggered with respect to each other so as not to vertically overlap each other, it may be difficult for the fumes generated in the processing space to flow into the buffer space. Accordingly, contamination of the light source by the fumes may be minimized.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A semiconductor manufacturing apparatus comprising:
a chamber having an inner space;
an optical window dividing the inner space into a processing space and a buffer space;
a stage disposed in the processing space, the stage having a support surface configured to support a substrate; and
a light source disposed in the buffer space and configured to irradiate the stage with light through the optical window,
wherein the optical window has a plurality of fluid communication holes defined therein providing a fluid path between the processing space and the buffer space.

2. The semiconductor manufacturing apparatus of claim 1, wherein the optical window includes:
a first optical plate including first optical patterns spaced apart to provide first communication holes through the first optical plate; and
a second optical plate spaced apart from the first optical plate in a vertical direction perpendicular to a surface of the first optical plate, the second optical plate including second optical patterns spaced apart to define second communication holes through the second optical plate, and
wherein at least some of the first communication holes vertically overlap the second optical patterns.

3. The semiconductor manufacturing apparatus of claim 2,
wherein the optical window further includes a third optical plate spaced apart from the first optical plate and the second optical plate in the vertical direction, the third optical plate including third optical patterns spaced apart to define third communication holes through the third optical plate, and
wherein each of the first communication holes vertically overlaps a respective one of the second optical patterns or a respective one of the third optical patterns.

4. The semiconductor manufacturing apparatus of claim 3,
wherein each of the first communication holes have a smaller width than each of the second communication holes and each of the third communication holes,
wherein each first communication hole of a first set of the first communication holes vertically overlaps a respective one of the second optical patterns, and
wherein each first communication hole of a second set of the first communication holes vertically overlaps a respective one of the third optical patterns.

5. The semiconductor manufacturing apparatus of claim 3,
wherein the optical window further includes a fourth optical plate spaced apart from the first optical plate, the second optical plate, and the third optical plate in the vertical direction, the fourth optical plate including fourth optical patterns spaced apart to define fourth communication holes through the fourth optical plate,
wherein each of the first communication holes vertically overlaps corresponding ones of the second optical patterns, corresponding ones of the third optical patterns, and corresponding ones of the fourth optical patterns, and
wherein each of the first optical patterns vertically overlaps a respective one of the second communication holes, a respective one of the third communication holes, and a respective one of the fourth communication holes.

6. The semiconductor manufacturing apparatus of claim 2,
wherein the optical window further includes a spacer located between the first optical plate and the second optical plate, and
wherein the spacer provides a vertical separation space between the first optical plate and the second optical plate.

7. The semiconductor manufacturing apparatus of claim 2, wherein the buffer space is located over the optical window, and the processing space is located under the optical window.

8. The semiconductor manufacturing apparatus of claim 7, further comprising:
a supply pipe fluidly connected to the chamber and configured to supply a purge gas into the buffer space; and
a discharge pipe fluidly connected to the chamber and configured to discharge the purge gas supplied by the supply pipe from the processing space,
wherein the purge gas flows from the buffer space into the processing space through the first communication holes and the second communication holes when the purge gas is supplied to the buffer space.

9. The semiconductor manufacturing apparatus of claim 8, wherein the chamber includes an outlet to which the discharge pipe is fluidly connected, and
wherein the outlet is located to a side of the stage.

10. A semiconductor manufacturing apparatus comprising:
a chamber having an inner space;
a stage disposed in the inner space, the stage having a support surface configured to support a substrate;
a light source disposed in the inner space and configured to irradiate the stage with light; and
an optical window located between the stage and the light source,
wherein the optical window includes:
a first optical plate including a plurality of first optical patterns spaced apart to define a plurality of first communication holes through the first optical plate; and
a second optical plate spaced apart from the first optical plate in a vertical direction perpendicular to a surface of the first optical plate, the second optical plate including a plurality of second optical patterns spaced apart to define a plurality of second communication holes, and
wherein the plurality of first optical patterns vertically overlap the plurality of second communication holes, respectively, but do not vertically overlap the plurality of second optical patterns.

11. The semiconductor manufacturing apparatus of claim 10, wherein each of the plurality of second optical patterns are located between corresponding adjacent ones of the plurality of first optical patterns when viewed in a plan view.

12. The semiconductor manufacturing apparatus of claim 11, wherein the plurality of first optical patterns and the plurality of second optical patterns extend lengthwise in a first direction perpendicular to the vertical direction when viewed in the plan view and are alternately arranged in a second direction crossing the first direction when viewed in the plan view.

13. The semiconductor manufacturing apparatus of claim 12, wherein side surfaces of the plurality of first optical patterns are vertically aligned with side surfaces of the plurality of second optical patterns, respectively.

14. The semiconductor manufacturing apparatus of claim 10, wherein the optical window further includes a third optical plate including a plurality of third optical patterns spaced apart to define a plurality of third communication holes, and
wherein each of the plurality of first optical patterns vertically overlaps at least one of the plurality of second communication holes and the plurality of third communication holes, but does not vertically overlap the plurality of second optical patterns and the plurality of third optical patterns.

15. The semiconductor manufacturing apparatus of claim 14, wherein each of the plurality of first communication holes has a smaller width than each of the plurality of second communication holes and each of the plurality of third communication holes,
wherein each first communication hole of a first set of the plurality of first communication holes vertically overlaps with a corresponding one of the plurality of second optical patterns, and
wherein each first communication hole of a second set of the plurality of first communication holes vertically overlaps with a corresponding one of the plurality of third optical patterns.

16. The semiconductor manufacturing apparatus of claim 15, wherein the first optical plate is located between the second optical plate and the third optical plate.

17. The semiconductor manufacturing apparatus of claim 14,
wherein the optical window further includes a fourth optical plate including a plurality of fourth optical patterns spaced apart to define a plurality of fourth communication holes, and
wherein each of the plurality of first optical patterns vertically overlaps with one of the plurality of second communication holes, the plurality of third communication holes, and the plurality of fourth communication holes, but does not vertically overlap the plurality of second optical patterns, the plurality of third optical patterns, and the plurality of fourth optical patterns.

18. A semiconductor manufacturing apparatus comprising:
a chamber having an inner space;
an optical window dividing the inner space into a processing space and a buffer space;
a stage disposed in the processing space, the stage having a support surface configured to support a substrate;
a light source disposed in the buffer space and configured to irradiate the stage with light through the optical window;
a supply pipe configured to supply a purge gas into the buffer space; and
a discharge pipe configured to discharge the purge gas supplied by the supply pipe from the processing space,
wherein the optical window has a plurality of communication holes providing a fluid path between the buffer space and the processing space,
wherein the buffer space is located over the optical window, and the processing space is located under the optical window, and
wherein the purge gas flows from the buffer space into the processing space through the plurality of communication holes when the purge gas is supplied by the supply pipe.

19. The semiconductor manufacturing apparatus of claim 18, wherein the supply pipe is provided above the optical window, and
wherein the discharge pipe is provided below the optical window.

20. The semiconductor manufacturing apparatus of claim 19, wherein the supply pipe is configured to supply the purge gas into the buffer space in a horizontal direction.
